(19) United States
(12) Patent Application Publication
(10) Pub. No.: US 2026/0247756 A1
(43) Pub. Date: Aug. 20, 2026

(54) SEMICONDUCTOR DEVICE

(71) Applicant: Rayleigh Vision Intelligence Co., Ltd., Hsinchu City (TW)

(72) Inventor: Jr-Hau He, Hsinchu City (TW)

(21) Appl. No.: 19/176,216

(22) Filed: Apr. 11, 2025

(30) Foreign Application Priority Data
Feb. 20, 2025 (TW) 114106334

(51) Int. Cl. H01L 23/00; H10H 20/831; H10H 20/85

(52) U.S. Cl. CPC H10H 20/831; H10H 20/8508; H10W 72/334

(57) ABSTRACT

The present application provides a semiconductor device, comprising a semiconductor component disposed on a glue layer, and the glue layer including a shrunken portion. The semiconductor component includes a semiconductor unit disposed on the glue layer, and a first cross-sectional area of the semiconductor unit is greater than a second cross-sectional area of the shrunken portion. By applying the shrunken portion of the glue layer for transferring the semiconductor device, a laser only needs to irradiate the shrunken portion to reduce a required laser sparkle area of the laser, thereby stably transferring the semiconductor device and avoiding damage to the semiconductor device.

### FIELD OF THE INVENTION

The present application relates to a semiconductor device, and more particularly to a semiconductor device capable of reducing the laser irradiation area during substrate transferring.

### BACKGROUND OF THE INVENTION

In prior art, the manufacturing and application processes of chips includes a plurality of key processes, such as the mass transfer process, which is an important step for transferring massive chips from an original substrate to a target substrate. In the mass transfer process, the selective irradiation of the laser beam is often relied on to transfer energy to the glue material at a bottom side of the chip to remove the glue material, so that the chip may be successfully transferred from the original substrate to the target substrate. However, in practical application, due to the limitation of the laser sparkle design and the glue material distribution, there are significant problems in the chip transfer process.

In the current laser for mass transfer, the design of the laser sparkle needs to fully cover a glue material area at the bottom of the chip to ensure the laser energy evenly irradiated to the glue material layer at the bottom of the chip, so that the glue material is heated up to desorb and release the chip. Since the design of the glue material distribution is usually a surface structure, its area is usually equivalent to a size of the chip or to slightly overlap the chip, therefore, a size and accuracy of the laser sparkle are directly limited by the glue material area, and the sparkle needs to cover the entire glue material area to ensure the normal falling and transferring of the chip.

However, when a large-area of the laser sparkle is irradiated, the wider coverage range of the laser sparkle may directly affect the chip body. When the laser sparkle not only irradiates the glue material but also irradiates the chip structure of the chip, the chip may be damaged, such as by the damage of the surface structure and the generation of internal thermal stress, which affects the light-emitting efficiency and stability of the chip. This situation is particularly evident in mass transfer of the chips, because uneven distribution of laser energy may cause local overheating or damage of the chip.

Secondary, due to the close arrangement of the chips, when a large area of the laser sparkle irradiates a designated chip, it often unexpectedly affects the adjacent chips to the designated chip, which is particularly evident when the chips are small and the spacing between the chips is narrow. When the laser beam irradiates the adjacent chips, it causes unintended heating of the non-target chips, which further causes chip damage or positioning errors, thereby reducing the overall transfer efficiency and yield. This unintended heating of the non-target chips may cause irreversible damage to subsequent process steps, affecting the performance of the final product.

In summary, although the laser mass transfer process has the potential to improve chip transfer efficiency, the design of the laser sparkle in the prior art needs to cover the entire area of the adhesive material, resulting in frequent problems of chip damage and heating of neighboring chips. The above problems not only increase the yield loss during chip transfer, but also challenge the stability and reliability of the overall process. Therefore, how to improve the accuracy and controllability of the laser sparkle and reduce the risk of damage to the chip body and neighboring chips is an urgent problem to be solved in the industry.

In view of the above problems of the prior art, the present application provides a semiconductor device with a glue layer with a gradually reduced area, so that the required laser sparkle area is reduced during mass transfer, reducing the risk of damage to the light-emitting chip and adjacent light-emitting chips.

### SUMMARY

An objective of the present application is to provide a semiconductor device, including a glue layer with a shrunken area, so that a required laser sparkle area of a laser for lifting off the glue layer from the semiconductor device is reduced to obtain a shrunken irradiation area during transferring the semiconductor device, thereby avoiding a laser damage to the semiconductor device by using the laser with the shrunken irradiation area.

To achieve the above-mentioned objects and effects, the present application provides a semiconductor device, comprising a light-transmitting substrate, a glue layer and a semiconductor component. The glue layer is disposed on the light-transmitting substrate. The glue layer includes a shrunken portion. The semiconductor component is disposed on the glue layer. The semiconductor component comprises a semiconductor unit, an insulation layer and an electrode layer. The semiconductor unit includes a first cross-sectional area. The insulation layer covers an outside of the semiconductor unit. The electrode layer is electrically connected to the semiconductor unit and is disposed under the semiconductor unit. The glue layer covers the electrode layer, and the first cross-sectional area is larger than a second cross-sectional area of the shrunken portion while the first and second cross-sectional areas are adjacent to both sides of the electrode layer respectively. The glue layer with the shrunken portion may stably transfer the semiconductor device and avoid damage of the semiconductor device.

In an embodiment of the present application, the semiconductor unit is a light emitting diode.

In an embodiment of the present application, the light-transmitting substrate is a sapphire substrate.

In an embodiment of the present application, the shrunken portion is disposed in a middle of the glue layer, so that the glue layer forms a funnel-shaped structure.

In an embodiment of the present application, the glue layer is connected to the light-transmitting substrate via the shrunken portion.

In an embodiment of the present application, the first cross-sectional area is the minimum cross-sectional area of the semiconductor unit.

In an embodiment of the present application, the shrunken portion of the glue layer is formed by an inductively coupled plasma etching or a reactive ion etching.

In an embodiment of the present application, the semiconductor component is separated from the light-transmitting substrate by irradiating a laser to the glue layer within a laser lift-off process.

In an embodiment of the present application,

In an embodiment of the present application, a material of the insulating layer is silicon nitride or silicon oxide.

In an embodiment of the present application, a thickness of the insulating layer is 500 nm~1000 nm.

In an embodiment of the present application, a thickness of the glue layer is 0.1 μm~10 μm, and the thickness of the glue layer is corresponding to an area of the semiconductor component.

In an embodiment of the present application, an absorption wavelength of the glue layer is from 200 nm to 400 nm.

### BRIEF DESCRIPTION OF THE DRAWINGS

FIG. 1 is a schematic diagram of a semiconductor device according to an embodiment of the present application;

FIGS. 2A-2B are schematic diagrams of transferring from an epitaxial substrate according to an embodiment of the present application;

FIGS. 3A-3B are schematic diagrams of the glue layer according to an embodiment of the application;

FIG. 4 is a schematic diagram of the glue layer according to another embodiment of the application; and

FIGS. 5A-5B are schematic diagrams of the glue layer according to another embodiment of the application.

### DETAILED DESCRIPTION

To overcome the above problems of the prior art, the present application provides a semiconductor device. The semiconductor device includes a light-transmitting substrate, a glue layer, and a semiconductor component. The glue layer is disposed on the light-transmitting substrate. The semiconductor component includes a semiconductor unit, an insulation layer, and an electrode layer. The semiconductor unit is disposed on the glue layer. The insulation layer covers an outside of the semiconductor unit. The electrode layer is electrically connected to the semiconductor unit and disposed under the semiconductor unit while the electrode layer penetrates the insulating layer. The glue layer has a shrunken portion. A first cross-sectional area of the semiconductor unit is larger than a second cross-sectional area of the shrunken portion. When the semiconductor device is transferred, the laser sparkle only covers the shrunken portion. The area of the laser sparkle is reduced. The laser beam does not damage the semiconductor device. The yield is improved. The manufacturing cost is reduced.

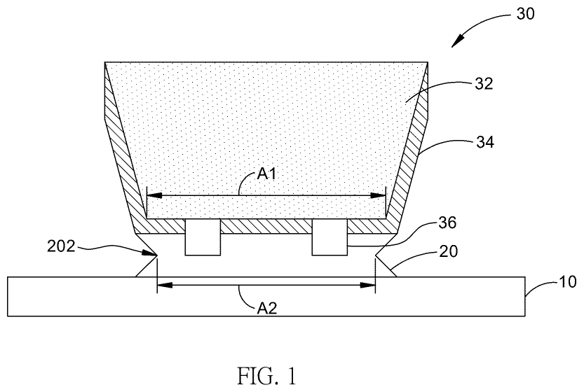

Referring to FIG. 1, which is a schematic diagram illustrating a structure of an embodiment of the application, as shown in the figure, the embodiment is the first embodiment. The embodiment is a semiconductor device, which includes a light-transmitting substrate 10, a glue layer 20, and a semiconductor component 30.

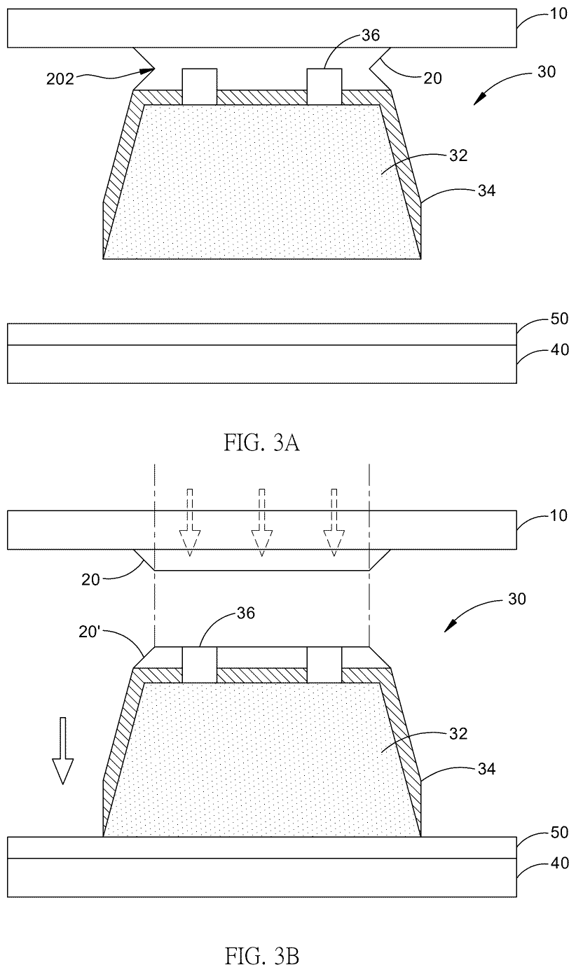

Referring to FIG. 1 again and referring to FIGS. 3A-3B, which are schematic diagrams of the glue layer of an embodiment of the application, as shown in the figures, the embodiment is the first embodiment. In the embodiment, the glue layer 20 is disposed on the light-transmitting substrate 10. The glue layer 20 has a shrunken portion 202. The semiconductor component 30 is disposed on the glue layer 20. The semiconductor component 30 includes a semiconductor unit 32, an insulation layer 34, and an electrode layer 36. The semiconductor unit 32 including a first cross-sectional area A1 is larger than a second cross-sectional area A2 of the shrunken portion 202, for example, the first cross-sectional area A1 is a surface area or a cross-sectional area of the surface where the electrode layer 36 is disposed on. The insulation layer 34 covers an outside of the semiconductor unit 32. The electrode layer 36 is electrically connected to the semiconductor unit 32 and disposed under the semiconductor unit 32 while the electrode layer 36 penetrates the insulating layer 34.

Continued to with the above, in the embodiment, the shrunken portion 202 of the glue layer 20 is disposed in a middle of the glue layer 20. Thereby, the glue layer 20 has a funnel-shaped structure disposed at a side of the glue layer 20.

In an embodiment, the semiconductor unit 32 of the semiconductor component 30 is a light-emitting diode (LED).

In an embodiment, the light-transmitting substrate 10 is a sapphire substrate.

In an embodiment, a material of the insulation layer 34 is silicon nitride or silicon oxide.

In an embodiment, a thickness of the insulation layer 34 is 500 nm~1000 nm. It is noted that a summation value of the first cross-sectional area A1 of the bottom surface of the semiconductor unit 32 and the thickness of the insulation layer 20 is greater than a value of the second cross-sectional area A2 of the shrunken portion 202.

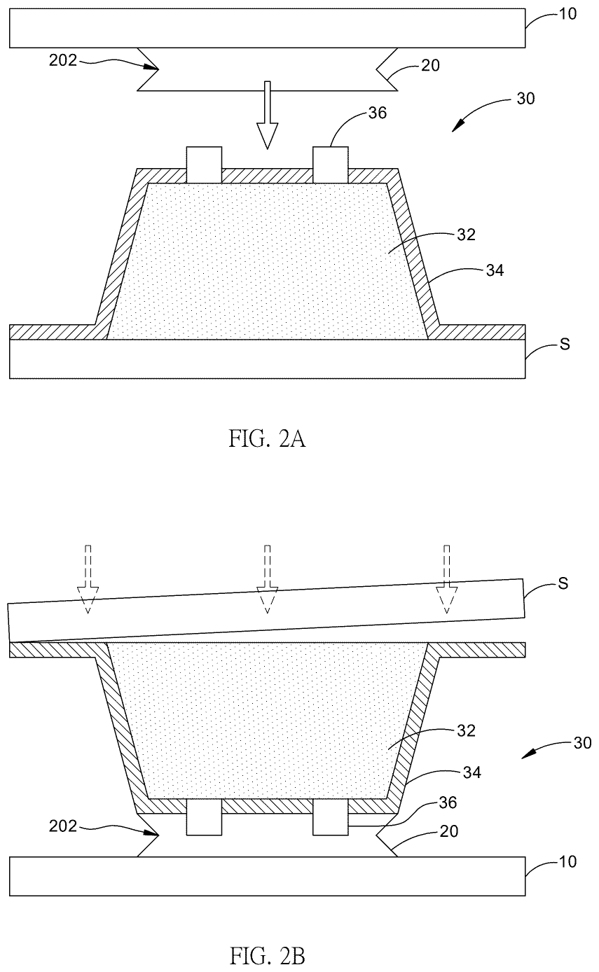

Referring to FIG. 1, FIG. 3A to FIG. 3B again, and further referring to FIG. 2A to FIG. 2B, which are schematic diagrams of transferring from an epitaxial substrate of an embodiment of the present application. As shown in FIG. 2A to FIG. 2B, when the semiconductor component 30 is manufactured, the semiconductor unit 32, the insulation layer 34, and the electrode layer 36 of the semiconductor component 30 is first disposed on an epitaxial substrate S, for example, after the semiconductor unit 32 and the electrode layer 36 of the semiconductor component 30 are formed on the epitaxial substrate S, the outside of the semiconductor unit 32 is coated with an insulation material to form the insulation layer 34. Then, as shown in FIG. 2A, the light-transmitting substrate 10 and the glue layer 20 are moved toward the semiconductor component 30 for transferring the semiconductor component 30 to the light-transmitting substrate 10 and the glue layer 20, and the semiconductor component 30 is separated from the epitaxial substrate S by a Laser Lift-off process, such as shown in FIG. 2B. Further, the glue layer 20 is etched to form the shrunken portion 202. The semiconductor component 30 is transferred correspondingly. After the transferring, the glue layer 20 is further etched to form the shrunken portion 202, as shown in FIG. 1.

Continued with the above, as shown in FIG. 3A, when the semiconductor component 30 is to be transferred to another substrate 40, the whole of the light-transmitting substrate 10, the glue layer 20 and the semiconductor component 30 is flipped over. Thereby, the semiconductor component 30 is facing another glue layer 50 and the another substrate 40. Herein, the Laser Lift-off process is used. A laser beam is irradiated to the shrunken portion 202 of the glue layer 20 correspondingly, as like cutting off from the shrunken portion 202 of the glue layer 20 correspondingly, while the material of the shrunken portion 202 is vaporized. As shown in FIG. 3B, the semiconductor component 30 and part of the glue layer 20 remain on the semiconductor component 30 fall off toward the another glue layer 50 and the another substrate 40.

Continued with the above, since the second cross-sectional area A2 of the shrunken portion 202 is smaller than the first cross-sectional area A1 of the semiconductor unit 32, such as the area of the bottom surface, the area of the laser sparkle may be limited to the size of the second cross-sectional area A2. The area of the laser sparkle is prevented from being too large. The Laser beam irradiating to the semiconductor unit 32 or the insulation layer 34 is avoided. The semiconductor component 30 is prevented from being damaged.

Continued with the above, further, the first cross-sectional area A1 is the minimum cross-sectional area of the semiconductor unit 32.

In an embodiment, the glue layer 20 is further etched by an inductively coupled plasma etching or a reactive-ion etching to form the shrunken portion 202.

In an embodiment, Inductively Coupled Plasma (ICP) is a plasma generation technology based on electromagnetic induction, widely used in chemical analysis, material processing, and semiconductor manufacturing. The principle is based on the alternating magnetic field generated by high-frequency alternating current in the induction coil, which realizes the ionization of gas and the stable maintenance of plasma by inducing the movement of electrons in the gas.

The generation process of ICP starts with the introduction of gas (e.g., argon), when high-frequency current passes through the induction coil, an alternating magnetic field is generated, which exerts force on free electrons in the gas, making them move at high speed. These electrons collide with gas molecules or atoms, triggering a series of ionization processes to form plasma. Due to the continuous action of the induction magnetic field, the electrons in the plasma are continuously accelerated, thereby maintaining a high-temperature stable plasma environment.

One of the main features of ICP is an electrodeless design. Traditional plasma generation techniques often rely on direct contact electrodes, but this approach is prone to erosion of electrode materials, leading to impurity contamination. ICP technology uses induction magnetic field for energy coupling, avoiding this problem, significantly improving the purity and stability of the plasma. In addition, ICP may generate extremely high plasma temperature, making it able to effectively decompose and excite various substances in the sample.

In an embodiment, Reactive-Ion Etching (RIE) is a plasma etching technology widely used in semiconductor manufacturing and micro-nano processing, combining chemical reaction and physical etching mechanisms to achieve precise selective removal of material surface. RIE technology, with its high directionality, high resolution and excellent material compatibility, has become a key step in the manufacturing of fine structures in modern semiconductor technology.

The process principle of reactive ion etching is based on the generation and control of plasma. In a reactive ion etching system, a specific gas (e.g., a fluoride or chloride gas) is injected into a reaction chamber, and a high-frequency electric field is applied to the gas by a radio frequency power source to excite the generation of plasma. The ions and radicals in the plasma will undergo chemical reactions with the material surface to generate volatile byproducts, which are then pumped away by a vacuum pump, thereby achieving material removal. In addition, the ions driven by the electric field will collide with the material surface in a highly directional manner, achieving physical etching and further enhancing the vertical directionality of the etching.

The combination of chemical reaction and physical etching is the core characteristic of reactive ion etching. The chemical reaction provides high selectivity, which may effectively distinguish the etching target from the mask material according to the material characteristics and the selection of the reaction gas; the physical etching brings excellent directionality, which is suitable for manufacturing deep and narrow structural features, such as transistor trenches, micro-electro-mechanical system (MEMS) structures, and fine patterns in optical devices.

The reactive ion etching technology has flexible process adjustability. By adjusting the gas composition, gas pressure, radio frequency power, and electrode bias, the reactive ion etching system may accurately control the etching rate, selectivity, and directionality. Different gases will generate different reactive ions, which are suitable for processing different materials. For example, fluorine-based gases are commonly used for etching silicon, while chlorine-based gases are suitable for etching metals and compound semiconductors.

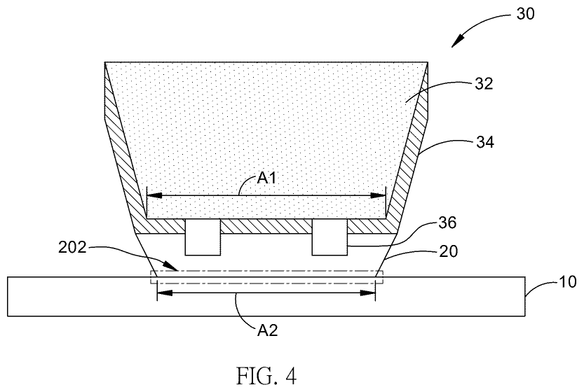

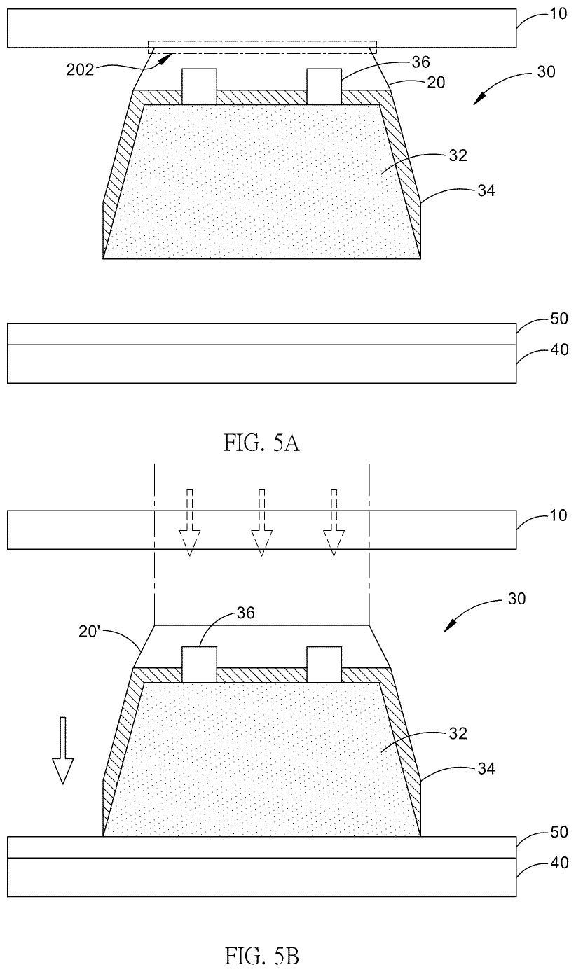

Referring to FIG. 4 and FIGS. 5A-5B, FIG. 4 is a schematic diagram of the glue layer according to another embodiment of the present application, and FIGS. 5A-5B are schematic diagrams of the glue layer according to another embodiment of the present application. As shown in the figures, the present embodiment is provided according to the first embodiment. The glue layer 20 is further connected to the light-transmitting substrate 10 by the shrunken portion 202, so that the glue layer 20 has an inverted trapezoid structure between the light-transmitting substrate 10 and the semiconductor component 30, particularly, between the light-transmitting substrate 10 and the insulating layer 34. Wherein the first cross-sectional area A1 of the semiconductor unit 32 is larger than the second cross-sectional area A2 of the shrunken portion 202 while the shrunken portion 202 of the glue layer 20 is gradually shrinking from the semiconductor component 30 to the light-transmitting substrate 10.

Referring to FIG. 5A again, when the semiconductor component 30 is to be transferred to the another substrate 40, the whole of the light-transmitting substrate 10, the glue layer 20 and the semiconductor component 30 is flipped over and the laser Lift-off process is used to irradiate the shrunken portion 202 of the glue layer 20 with the laser beam, so that the material of the shrunken portion 202 is vaporized, as shown in FIG. 5B, and the semiconductor component 30 and the glue layer 20 are dropped.

In this embodiment, more of the glue layer 20 is further dropped together with the semiconductor component 30. The other elements and their operating relations of the present embodiment are the same as those of the above embodiments, and thus are not described herein.

In the above embodiments, the semiconductor device is exemplified by a light-emitting device, the semiconductor component 30 may be a light-emitting element, and the semiconductor unit 32 may be a light-emitting unit, such as a light-emitting diode.

In the above embodiments, a thickness of the glue layer 20 is 0.1 μm~10 μm, the thickness of the glue layer 20 corresponding to the area of the semiconductor component 30 with better Lift-off effect as shown in following table.

Table the relationship between the thickness of the glue layer 20 and the area of the semiconductor component 30

| thickness of | area of semiconductor |
|---|---|
| glue layer (μm) | component (μm²) |
| 1~5 | <100 |
| 0.5~4 | 100~799 |
| 0.1~3 | 800~2000 |

This application is to provide the semiconductor structure with a respective thickness of the glue layer 20 corresponding to a respective area of the semiconductor component 30 for reducing the semiconductor component 30 in damage and offset flipping.

An absorption wavelength of the glue layer 20 is from 200 nm to 400 nm, for example, a material of the glue layer 20 is selected from a Laser Lift-off material or a Laser Debonding material, which commonly is a polyimide material or silicon oxide material, which is usually used to absorb the energy of the laser in 355 nm, even to absorb the energy of the laser in 248 nm or 266 nm.

In summary, the present application provides a semiconductor device, including a light-transmitting substrate, a glue layer disposed on the light-transmitting substrate and including a shrunken portion disposed at a portion of the glue layer, such as gradually shrinking in one direction toward a light-transmitting substrate or shrinking in a middle of the glue layer, and a semiconductor component is disposed on the glue layer and includes a first cross-sectional area, and the shrunken portion includes a second cross-sectional area smaller than the first cross-sectional area of the semiconductor component. When the semiconductor component is transferred, an area of a laser sparkle only needs to cover the shrunken portion, so that a required laser sparkle area is reduced. The present application may solve the problem of the prior art, that the laser sparkle needs to cover the bottom area of the semiconductor component in the mass transfer process, which causes that the semiconductor component or the insulating layer is irradiated by laser beam, resulting in damage to the chip or local overheating, and increasing the manufacturing cost.

Therefore, the present application is undoubtedly novel, progressive, and applicable to the industry. Therefore, a patent application is submitted in accordance with that the patent will be granted as soon as possible.

The above description is only an embodiment of the present application and is not intended to limit the scope of the present application. Therefore, any equivalent changes and modifications made in accordance with the shape, structure, features, and spirit described in the patent application scope of the present application shall be included in the patent application scope of the present application.

What is claimed is:

1. A semiconductor device, comprising:
a light-transmitting substrate;
a glue layer, disposed on the light-transmitting substrate, the glue layer including a shrunken portion; and
a semiconductor component, disposed on the glue layer, the semiconductor component comprising:
a semiconductor unit, including a first cross-sectional area;
an insulation layer, covering an outside of the semiconductor unit; and
an electrode layer, electrically connected to and disposed under the semiconductor unit while the electrode layer penetrates the insulating layer, wherein the glue layer covers the electrode layer, the first cross-sectional area larger than a second cross-sectional area of the shrunken portion while the first and second cross-sectional areas are adjacent to both sides of the electrode layer respectively.

2. The semiconductor device of claim 1, wherein the semiconductor unit is a light-emitting diode.

3. The semiconductor device of claim 1, wherein the light-transmitting substrate is a sapphire substrate.

4. The semiconductor device of claim 1, wherein the shrunken portion is disposed in a middle section of the glue layer, so that the glue layer forms a funnel structure.

5. The semiconductor device of claim 1, wherein the glue layer connects the light-transmitting substrate via the shrunken portion.

6. The semiconductor device of claim 1, wherein the first cross-sectional area is a minimum cross-sectional area of the semiconductor unit.

7. The semiconductor device of claim 1, wherein the shrunken portion of the glue layer is formed by an inductively coupled plasma etching or a reactive ion etching.

8. The semiconductor device of claim 1, wherein the semiconductor component is separated from the light-transmitting substrate by irradiating a laser to the glue layer within a laser lift-off process.

9. The semiconductor device of claim 1, wherein a material of the insulating layer is silicon nitride or silicon oxide.

10. The semiconductor device of claim 1, wherein a thickness of the insulating layer is 500 nm to 1000 nm.

11. The semiconductor structure of claim 1, wherein a thickness of the glue layer is 0.1 μm~10 μm, and the thickness of the glue layer is corresponding to an area of the semiconductor component.

12. The semiconductor structure of claim 1, wherein an absorption wavelength of the glue layer is from 200 nm to 400 nm.
